(19) United States
(12) Patent Application Publication
(10) Pub. No.: US 2025/0147073 A1
(43) Pub. Date: May 8, 2025

(54) PROBE CARD AND METHOD FOR DESIGN PROBE CARD AND MEASURING METHOD AND SYSTEM FOR DETECTING DEVICE UNDER TEST USING THE PROBE CARD

(71) Applicant: MPI Corporation, Zhubei City (TW)

(72) Inventors: CHIEN-MING LO, Zhubei City (TW); Hsuan-Ti Yeh, Zhubei City (TW); Chih-Hao Ho, Zhubei City (TW); Horng-Chuan Sun, Zhubei City (TW); Chien-Ming Huang, Zhubei City (TW); Chia-Hung Liu, Zhubei City (TW)

(21) Appl. No.: 18/934,482

(22) Filed: Nov. 1, 2024

Related U.S. Application Data
(60) Provisional application No. 63/547,143, filed on Nov. 2, 2023.

(51) Int. Cl. G01R 1/073; G01R 3/00

(52) U.S. Cl. CPC G01R 1/07378; G01R 1/07342; G01R 3/00

(57) ABSTRACT

The present invention provides a probe card. The probe card comprises a circuit board, a cantilever-type space transformer electrically connected to the circuit board, and a vertical probe head electrically connected to the cantilever-type space transformer. The vertical probe head comprises a probe base and a plurality of vertical probes. The cantilever-type space transformer comprises a mounting base and a plurality of cantilever converting probes, wherein each cantilever converting probe has a fixed segment and an exposed segment. The fixed segment is secured to the mounting base, and the exposed segment is located outside the mounting base. The fixing segment enters from the side of the mounting base and forms a contact at the bottom of the mounting base.

This application claims the benefit of U.S. Provisional Application No. 63/547,143, filed on Nov. 2, 2023, the subject matter of which is incorporated herein by reference.

### BACKGROUND OF INVENTION

### 1. Field of the Invention

The invention relates to a probe card, a method for designing the probe card, and a test method and test system using the probe card.

### 2. Description of the Prior Art

Wafer Acceptance Test (WAT), an inspection process utilized in front-end manufacturing process of wafer, is a critical step in the semiconductor production process for mainly ensuring the quality and performance of the device under test (i.e., wafer), thereby identifying potential issues before the wafers entering to subsequent processes (e.g., dicing, packaging, etc.) so as to reduce costs and improve product quality. WAT primarily tests the pads located on the wafer scribe line. The testing method utilizes probes of the probe card to pads of the wafer scribe line. The other end of the probe card is connected to the testing equipment of the wafer acceptance testing system to perform measurements on the wafer.

With advancements in semiconductor manufacturing processes, chip sizes are becoming increasingly smaller in which the pad size and the pad pitch are trending towards miniaturization such that when the cantilever converting probes of conventional cantilever converting probe cards (CPCs) are relatively moved to contact the pads of the chip, the probe tips may experience lateral movement due to vertical relative motion between the probe tips and the wafer whereby the probe tips is shifted out of the pad area, thereby resulting in an invalid contact with the pads.

### SUMMARY OF THE INVENTION

The present invention provides a probe card that combines the cantilever converting probe of a cantilever converting probe card with a vertical probe head so as to effectively and stably test the device under test (DUT) thereby addressing the issue of ineffectively electrical test of the conventional cantilever converting probe card caused due to the miniaturization of pad sizes and pad pitch.

Accordingly, the present invention provides a probe card suitable for performing WAT on a wafer, wherein the probe card comprises a circuit board, a cantilever-type space transformer electrically connected to the circuit board, and a vertical probe head electrically connected to the cantilever-type space transformer. The vertical probe head comprises a probe base and vertical probes. The probe base comprises an upper guide plate unit and a lower guide plate unit. The upper guide plate unit has an upper guide plate with upper guide holes passing therethrough, while the lower guide plate unit has a lower guide plate with lower guide holes passing therethrough. Both the upper and lower guide plate units have upper and bottom surfaces, respectively, and an accommodating space is formed between the bottom surface of the upper guide plate unit and the upper surface of the lower guide plate unit. Each vertical probe comprises a probe tail, a probe body, and a probe tip. The probe tail passes through the upper guide holes, the probe body is positioned within the accommodating space, and the probe tip passes through the lower guide holes. The cantilever-type space transformer comprises a mounting base and cantilever converting probes. Each cantilever converting probe has a fixed segment and an exposed segment. The fixed segment is secured to the mounting base, while the exposed segment extends outside the mounting base. The fixed segment enters the mounting base from lateral side of the mounting base and forms a contact on a bottom surface of the mounting base.

In addition, if the spacing between adjacent cantilever converting probes is not properly adjusted, it can easily induce coupling capacitance, thereby affecting the results of electrical testing. Therefore, the arrangement of adjacent cantilever converting probes is necessary to be adjusted so as to reduce coupling capacitance value therebetween such that the energy storage effect between probes can be reduced thereby enhancing the stability of leakage current testing.

Accordingly, in one embodiment, the cantilever converting probe comprises a first converting probe and a second converting probe. The first and second converting probes are adjacent to each other without a contact. The fixed segments of the first and second converting probes comprises insertion segments that extend from a lateral side of a fixing portion, wherein each insertion segment of the cantilever converting probes further comprises a head section located away from the lateral side of the fixing portion and a tail section adjacent to the lateral side of the fixing portion. In the head sections of the insertion segments of the first and second converting probes, the corresponding positions of the two insertion segments have a shortest head distance. In the tail sections of the insertion segments of the first and second converting probes, there is a shortest tail distance, which is greater than the shortest head distance. In another embodiment, the shortest distance between the corresponding positions of the insertion segments of the first and second converting probes are gradually decreased from the positions entering the lateral side of the fixing portion.

Moreover, in order to avoid contact instability caused by the position shifting of probe tip of the cantilever converting probe due to sway induced by the contact force when the cantilever converting probe electrically contact with the vertical probe of the vertical probe head, in one embodiment, the cantilever-type space transformer is arranged on the circuit board and the mounting base comprises a base frame having an upper surface facing the circuit board and a first through-hole. The fixing portion is positioned within the first through-hole and extends toward the upper surface of the base frame and the fixed segment is encased in the fixing portion.

Furthermore, for ensuring that the structure of the probe card is suitable for leakage current testing, an electrical pad ring is arranged on the bottom surface of the circuit board to solder the cantilever converting probes so as to ensure the leakage current being directed to ground through the guard circuit pattern without flowing to other electrical pad rings, thereby keeping the leakage current within the specification. In one embodiment, the circuit board further comprises a plurality of leakage current protection pad, each of which is arranged on a base plate mounted on the circuit board through bonding material. The leakage current protection pad also comprises signal circuit patterns surrounded by guard pattern. If the leakage current protection pad does not meet the leakage current test specifications, the base plate can be removed and replaced with a new one that has leakage current protection pad so as to provide a remedial mechanism for overcoming issue that the leakage current protection pad does not comply with leakage current test specifications.

Moreover, the flatness of the reinforcing member is less than that of the circuit board. When the mounting base is arranged on the reinforcing member, the bottom surface of the fixing portion of the mounting base has a first flatness. When the mounting base is arranged on the circuit board, the bottom surface of the fixing portion has a second flatness, where the first flatness is less than the second flatness. When replacement of vertical probe of the vertical probe head is performed while the mounting base is arranged on the circuit board, the condition that the vertical probe of the vertical probe head could not be electrically connected to the cantilever-type space transformer stably is inducted due to poor second flatness of bottom surface of the fixing portion thereby causing the poor stability of the WAT. However, when replacement of vertical probe head is performed on the probe card having the mounting base arranged on the reinforcing member, since the bottom surface of the fixing portion has better first flatness, the vertical probe of the vertical probe head could be electrically connected to the cantilever-type space transformer stably thereby enhancing the stability of WAT.

In one embodiment, the material of each cantilever converting probe is beryllium, copper, rhenium, tungsten, gold, silver, or an alloy selected from at least two of thereof.

In one embodiment, the contact of each cantilever converting probe is one end of a probe body of the fixed segment, or the contact of each cantilever converting probe is a contact pad coupled to the end of the prob body of the fixed segment.

In one embodiment, the fixed segment is conical.

In one embodiment, the hardness of the cantilever converting probe is greater than 245 MPa, and its electrical resistance is less than 200 mΩ.

Additionally, when performing WAT using the probe card of the present invention, it prevents cantilever converting probe from being swayed due to the vibration of test environment. With a hardness greater than 245 MPa, the vibration of cantilever converting probes could be prevented thereby ensuring stable test results. Furthermore, a leakage current between two adjacent cantilever converting probes, i.e. electric current in one cantilever converting probe flowing to another cantilever converting probe, should also be avoided. When the electrical resistance of the cantilever converting probe is less than 200 mΩ, the leakage current between adjacent cantilever converting probes can be minimized to the maximum extent.

In order to solve the issue of coupling capacitance interference between adjacent cantilever converting probes and to improve the accuracy of electrical measurements, the influence of coupling capacitance is reduced by adjusting the distance or gap between the cantilever converting probes. In one embodiment, the present invention provides a method for designing probe card wherein the probe card comprises a circuit board, a cantilever-type space transformer, and a vertical probe head. The cantilever-type space transformer is electrically connected to the circuit board, and the vertical probe head is electrically connected to the cantilever-type space transformer. The cantilever-type space transformer comprises a mounting base and a plurality of cantilever converting probes comprising a first converting probe and a second converting probe adjacent to each other. The method for designing probe card comprises steps of adjusting actual coupling capacitance between the first and second converting probes to meet a threshold value of coupling capacitance according to a distance between the first converting probe and the second converting probe under a condition that the distance between one end of the first converting probe and the second converting probe is fixed. In another embodiment, the mounting base of the cantilever-type space transformer comprises a fixing portion. Each cantilever converting probe comprises a fixed segment and an exposed segment, wherein the fixed segment is secured to the fixing portion of the mounting base, while the exposed segment is out of the fixing portion for being electrically connected to the circuit board. The step of adjusting the actual coupling capacitance between the first and second converting probes comprises steps of adjusting a relative distance between the fixed segments of the first and second converting probes so as to adjust the actual coupling capacitance therebetween.

The present invention further provides a testing method, comprising steps of providing the aforementioned probe card, enabling probe tips of the vertical probes on the probe card correspondingly contact a plurality of conductive pads on the device under test, and, finally, transmitting test signals to the device under test through the probe card.

The present invention provides a testing system, comprising a carrier platform and a probe card. The carrier platform supports the device under test. The probe card is electrically connected to the device under test through the vertical probes of the probe card contacting the device under test.

### BRIEF DESCRIPTION OF THE DRAWINGS

The present invention will now be specified with reference to its preferred embodiment illustrated in the drawings, in which:

FIG. 1A is an exploded view of the probe card according to the first embodiment of the present invention;

FIGS. 1B and 1C are perspective views of the probe card observed from different angles according to the first embodiment of the present invention, observed from different angles;

FIGS. 1D and 1E are cross-sectional views of FIG. 1B;

FIG. 1F is a cross-sectional view of the probe card according to the second embodiment of the present invention;

FIG. 2A is a schematic view of the probe card according to the third embodiment of the present invention;

FIG. 2B is a schematic view of the probe card according to the fourth embodiment of the present invention;

FIG. 3A is a bottom view of the probe card according to the first embodiment of the present invention;

FIG. 3B is a schematic view of an embodiment of the leakage current protection pad of the probe card according to the present invention;

FIG. 4A is a schematic view of the probe card according to the fifth embodiment of the present invention;

FIG. 4B is a schematic view of the probe card according to the sixth embodiment of the present invention;

FIG. 5 is a flowchart of an embodiment of method for designing the probe card according to the present invention;

FIG. 6 is a schematic view of an embodiment of the test system according to the present invention; and

FIG. 7 is a flowchart illustrating an embodiment of the method for testing semiconductor wafers using the probe card according to the present invention.

### DESCRIPTION OF THE PREFERRED EMBODIMENT

Various exemplary embodiments are provided below to make the disclosure of the present invention more detailed and complete. However, these exemplary embodiments are not intended to limit the scope of the present invention.

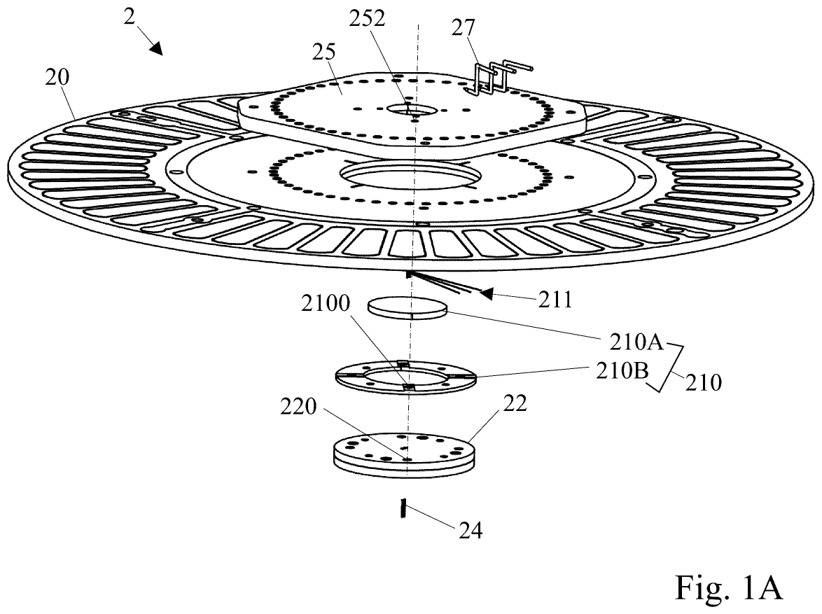

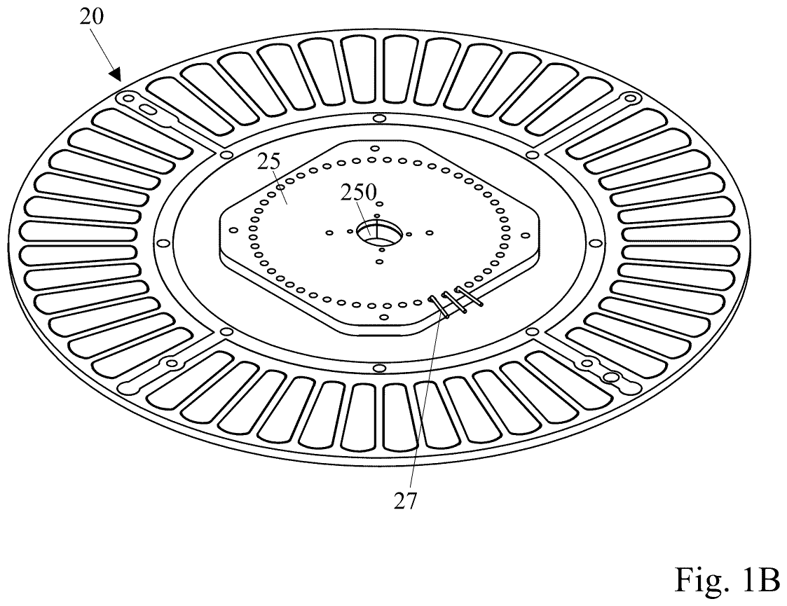

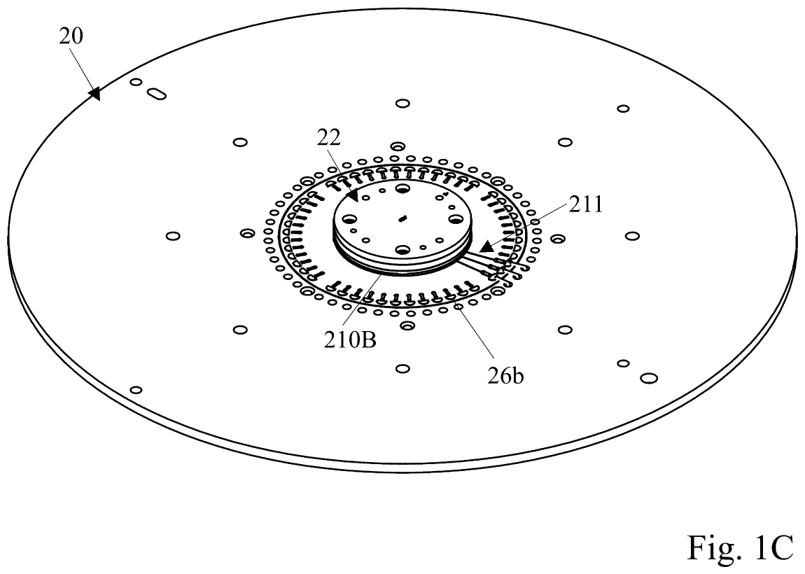

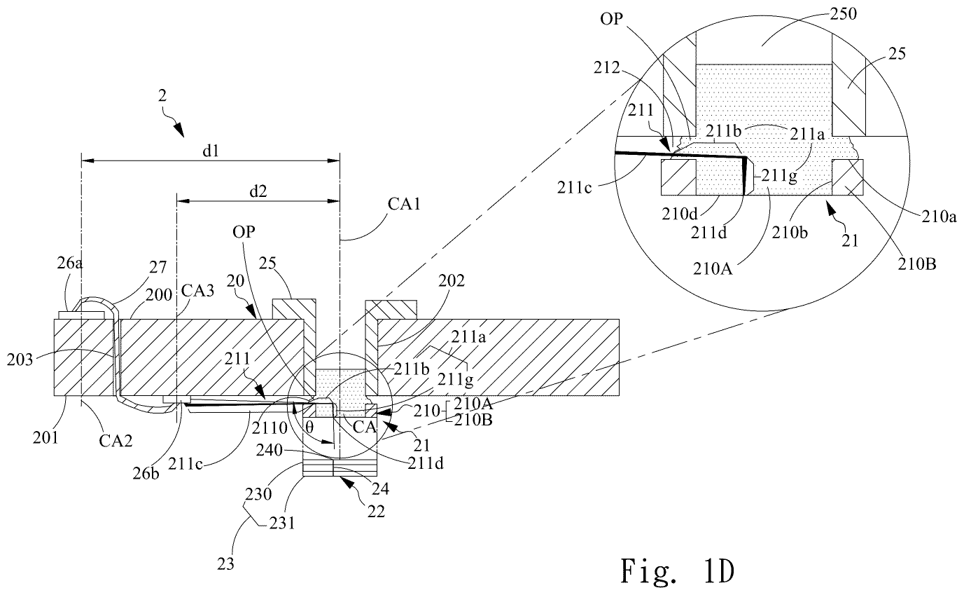

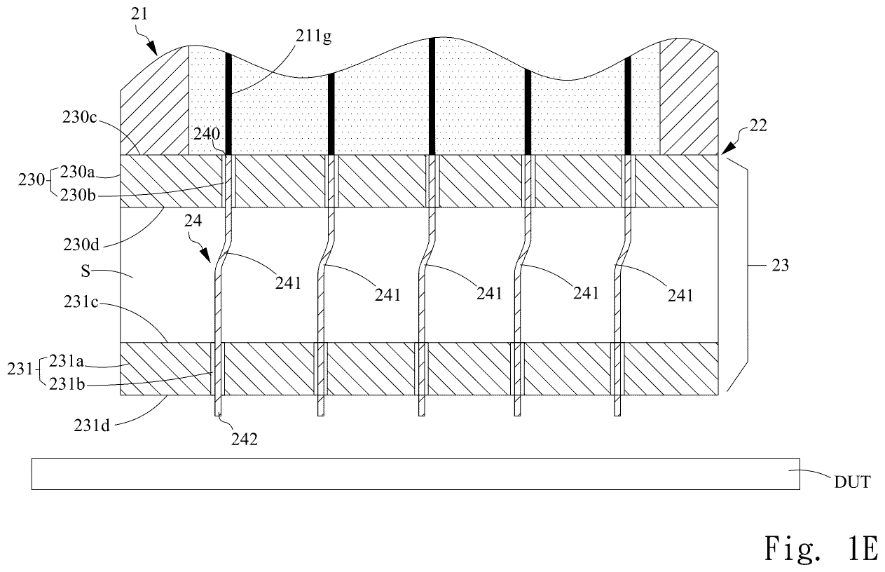

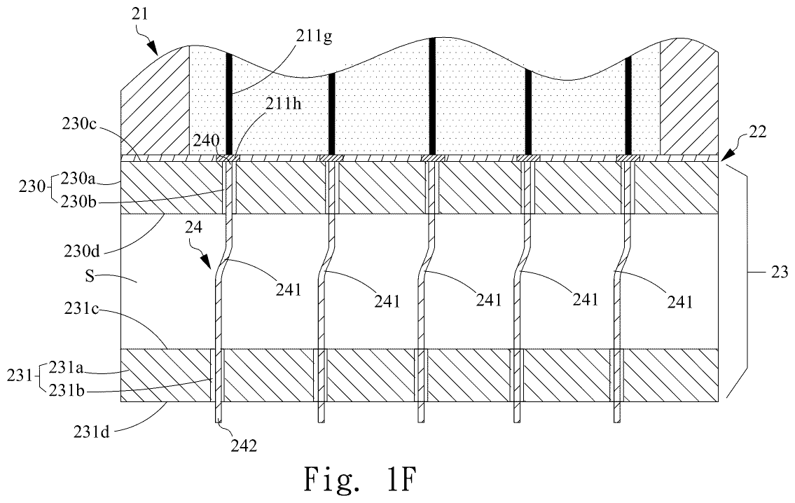

Please refer to FIGS. 1A to 1E, in which FIG. 1A is an exploded view of the probe card 2 according to the first embodiment of the present invention, FIGS. 1B and 1C are perspective views of the probe card 2 from different angles in the first embodiment, wherein FIG. 1B shows a perspective view from an oblique top angle, and FIG. 1C shows a perspective view from an oblique bottom angle, and FIGS. 1D and 1E are cross-sectional views of FIG. 1B. Specifically, these cross-sectional views are obtained along the longitudinal direction from one endpoint on the outer circumference of the circular circuit board 20 to the opposite endpoint on the same circumference, when the probe card 2, as shown in FIG. 1A, is placed parallel to the ground and all components are fully assembled, wherein the distance between these two endpoints corresponds to the diameter of the outer circumference of the circuit board 20. In particular, the cross-sectional view in FIG. 1D provides a clearer illustration of the detailed structures of the circuit board 20, the reinforcement member 25, the cantilever-type space transformer 21, and the positional relationships among these components. Meanwhile, the cross-sectional view in FIG. 1E more clearly illustrates the detailed structure of the vertical probe head 22.

The probe card 2 comprises a circuit board 20, a cantilever-type space transformer 21, and a vertical probe head 22. The cantilever-type space transformer 21 is electrically connected to the circuit board 20, and the vertical probe head 22 is electrically connected to the cantilever-type space transformer 21.

The circuit board 20 comprises an upper surface 200 and a bottom surface 201. The circuit board 20 further comprises leakage current protection pads 26a and 26b, a coaxial cable 27, and a first through-hole 203. The first through-hole 203 is formed between the upper surface 200 and the bottom surface 201 and penetrates the circuit board 20. The leakage current protection pad 26a is disposed on the upper surface 200, while the leakage current protection pad 26b is disposed on the bottom surface 201. One end of the coaxial cable 27 is electrically connected to the leakage current protection pad 26a, and the other end is electrically connected to the leakage current protection pad 26b. The coaxial cable 27 passes through the circuit board 20 via the first through-hole 203.

One purpose of using the leakage current protection pads 26a and 26b in this embodiment is to prevent current leakage. Specifically, before conducting WAT, the probe card 2 may first undergo a leakage current test to ensure the leakage current meets standard specifications. Otherwise, during the WAT, the leakage current of the probe card could potentially damage the wafer. For example, the standard specification may require the leakage current to be less than 1 pA (1×10⁻¹² A). In other possible embodiments, the circuit board 20 may use other types of pads and is not limited to the leakage current protection pads 26a and 26b.

One purpose of using the coaxial cable 27 in this embodiment is to enable high-frequency testing. In other possible embodiments, the circuit board 20 may use other types of cables, which are not limited to the coaxial cable 27; however, such alternatives may not be suitable for high-frequency testing.

The cantilever-type space transformer 21 comprises a mounting base 210 and cantilever converting probes 211. In some embodiments according to the present invention, the material of the cantilever converting probes 211 could be beryllium, copper, rhenium, tungsten, gold, or silver, or an alloy selected from at least two of thereof. Furthermore, in certain embodiments of the present invention, the hardness of the cantilever converting probes 211 is greater than 245 MPa, and the electrical resistance is less than 200 mΩ.

In the present embodiment, the mounting base 210 comprises a fixing portion 210A and a base frame 210B. The material for forming the fixed structure of the fixing portion 210A is a polymer material (e.g., epoxy resin). The base frame 210B has an annular structure in which the hollow region CA surrounded by the annular structure is defined as a first through-hole 210b. The first through-hole 210b is filled with epoxy resin. The probe card of the embodiment further comprises a reinforcement member 25, which is detachably arranged in the through-hole 202 of the circuit board 20. The mounting base 210 is connected to the reinforcement member 25 having a through-hole 250 wherein the outer wall of the reinforcement member 25 passes through the through-hole 202 of the circuit board 20. The fixing portion 210A also fills the through-hole 250 wherein a part of the epoxy resin overflowing from the gap between the upper surface of the base frame 210B and the reinforcement member 25 forms an overflow part OP.

It is noted that those skilled in the art can appropriately modify the structure of the mounting base 210 of the present embodiment. The reinforcement member 25 may also be omitted, or its structure or position relative to the mounting base may be altered, as long as the cantilever converting probes 211 can be securely fixed and stably electrically connected to the circuit board 20 and the vertical probe head 22. For example, in other possible embodiments of the present invention, the reinforcement member 25 of the probe card may be configured as non-removable. Alternatively, in other possible embodiments, the reinforcement member 25 may be omitted from the probe such that a gap is formed between the upper surface of the base frame 210B and the bottom surface 201 of the circuit board 20. In such cases, part of the epoxy resin would overflow from the gap to form the overflow part OP.

Compared to other possible embodiments of the present invention, this embodiment provides at least the following advantages comprising that firstly, the reinforcing member 25 is utilized to enhance the securing effect between the mounting base 210 and the circuit board 20, thereby improving the stability of the electrical connection between the pads of the mounting base 210 and the probe tail 240 of the vertical probes 24 of the vertical probe head 22, secondly, the structure of the reinforcing member 25 and its positional arrangement within the through-hole 202 of the circuit board 20 generate better securing effect and enhanced stability, and thirdly, the reinforcing member 25 is detachable, compared to other possible embodiments of the present invention, it allows for the replacement of corresponding cantilever-type space transformer 21 and reinforcing members 25 onto the same circuit board 20 according to different DUTs, thereby reducing material costs. Specifically, since the mounting base 210 of the cantilever-type space transformer 21 is arranged on the reinforcing member 25, the reinforcing member 25 can be detached from the circuit board 20 by detaching the exposed segment 211c of the cantilever-type converting probes 211 from the leakage current protection pad 26b.

The cantilever-type converting probes 211 sequentially comprises a fixed segment 211a and an exposed segment 211c. The fixed segment 211a is secured within the fixing portion 210A of the mounting base 210, while the exposed segment 211c arranged outside the fixing portion 210A and extends toward the direction to the circuit board 20. The exposed segment 211c is used for the electrical connection to the pads of the circuit board 20. The fixed segment 211a is inserted through the gap between the upper surface of the base frame 210B and the reinforcing member 25, i.e., the lateral side of the fixing portion 210A, and forms pads 211d at the under surface (or bottom surface 210d) of the fixing portion 210A of the mounting base 210, which are used for electrical contact with the probe tail 240 of the vertical probes 24.

In the present embodiment, the shape of the fixed segment 211a is a conical shape, such as a cone or a pyramid. It should be noted that the shape of the fixed segment 211a is not limited to a conical shape. In other possible embodiments of the present invention, those skilled in the art may use thinner probes that does not necessarily need to have a conical shape to accommodate the reduced pitch of pad on the wafer. In the present embodiment, the fixed segment 211a of the probe card adopts a conical structure. Compared to other possible embodiments of the present invention, the conical structure of the fixed segment 211a allows the adjustments of the size of the contact between the cantilever converting probe 211 and the probe tail of the vertical probe 22, thereby achieving stability of electrical contact.

In this embodiment, the fixed segment 211a is a probe with an angled structure, i.e., the fixed segment 211a comprising an insertion segment 211b and a contact segment 211g connected to the insertion segment 211b with an included angle. The contact segment 211g can be regarded as the probe tip of the cantilever converting probe 211. However, this is not a limitation of the present invention. For example, in other possible embodiments of the present invention, the insertion segment 211b may have a curved probe structure having one end protruded out of the fixing portion 210A through a bending curvature so as to form a contact electrical connecting with the probe tails 240 of the vertical probes 24. Compared to other possible embodiments of the present invention, the angled structure in the present embodiment makes alignment of the contact 211d of the cantilever converting probe 211 more easily when mounting the cantilever converting probe 211 onto the mounting base 210.

The vertical probe head 22 comprises a probe base 23 and a plurality of vertical probes 24. The probe base 23 comprises an upper guide plate unit 230 and a lower guide plate unit 231. The upper guide plate unit 230 comprises at least one upper guide plate 230a and a plurality of upper guide holes 230b passing through the upper guide plate 230a while the lower guide plate unit 231 comprises at least one lower guide plate 231a and a plurality of lower guide holes 231b passing through the lower guide plate 231. The upper guide plate unit 230 has an upper surface 230c and a lower surface 230d, while the lower guide plate unit 231 has an upper surface 231c and a lower surface 231d. An accommodating space S is formed between the lower surface 230d of the upper guide plate unit 230 and the upper surface 231c of the lower guide plate unit 231. Each vertical probe 24 comprises a probe tail 240, a probe body 241, and a probe tip 242. The probe tail 240 passes through the upper guide hole 230b and is used for electrical contact with the cantilever-type space transformer 21. The probe body 241 is located within the housing space S, and the probe tip 242 passes through the lower guide hole 231b for electrical contact with the DUT.

In this embodiment, the vertical probe head 22 is arranged on the reinforcing member 25. Specifically, the securing element, such as securing element 28, for example, is utilized to pass through the through hole 220 of the vertical probe head 22 and the through hole 2100 of the base frame 210B of the mounting base 210, and are then fastened into the locking holes 252 of the reinforcing member 25 or to pass through the abutting ring 251 of the reinforcing member 25 whereby the securing element are secured by using a nut so as to secured the vertical probe head 22 on the reinforcing member 25. As a result, the vertical probe head 22 and the mounting base 210 are directly arranged on the reinforcing member 25. The reference for the flatness standard with respect to the vertical probe head 22 and the mounting base 210 is determined by the reinforcing member 25. The flatness of the reinforcing member 25 is less than that of the circuit board 20. The bottom surface 210d of the fixing portion 210A of the mounting base 210 has a first flatness while when the mounting base 210 is arranged on the reinforcing member 25, the bottom surface 210d of the fixing portion 210A has a second flatness while when the mounting base 210 is arranged on the circuit board 20, wherein the first flatness is less than the second flatness. When the vertical probe head 22 of the probe card having the mounting base 210 arranged on the circuit board 20 is replaced, the poor second flatness of the bottom surface 210d of the fixing portion may result in unstable electrical connections between the vertical probes 24 of the vertical probe head 22 and the cantilever-type space transformer 21 thereby inducing the instability of WAT. When the vertical probe head 22 of the probe card having the mounting base 210 arranged on the reinforcing member 25 is replaced, the better first flatness of the bottom surface 210d of the fixing portion may result in stable electrical connections between the vertical probes 24 of the vertical probe head 22 and the cantilever-type space transformer 21, thereby improving the stability of WAT.

In the present embodiment, the contact 211d of each cantilever converting probe 211 is at the end of the fixed segment 211a, and the lowest position of the end of the fixed segment 211a is aligned with the plane with respect to the under surface (or called bottom surface 210d) of the fixing portion 210A of the mounting base 210. In other possible embodiments of the present invention, the lowest position of the end of the fixed segment 211a may be above or below the plane of the under surface (or called bottom surface 210d) of the fixing portion 210A of the mounting base 210. In addition, in another embodiment, as shown in FIG. 1F, the pad 211d of the cantilever converting probe 211 is an enlarged pad 211h, which is positioned below the plane of under surface (or called bottom surface 210d) of the fixing portion 210A of the mounting base 210. Through the design of the contact pad 211h, the stability of the electrical contact between the cantilever converting probe 211 of the cantilever-type space transformer 21 and the vertical probe 24 of the vertical probe head 22 can be improved.

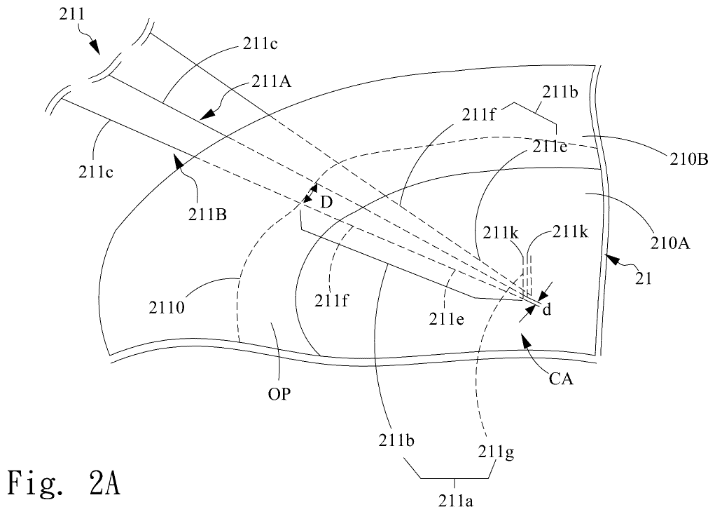

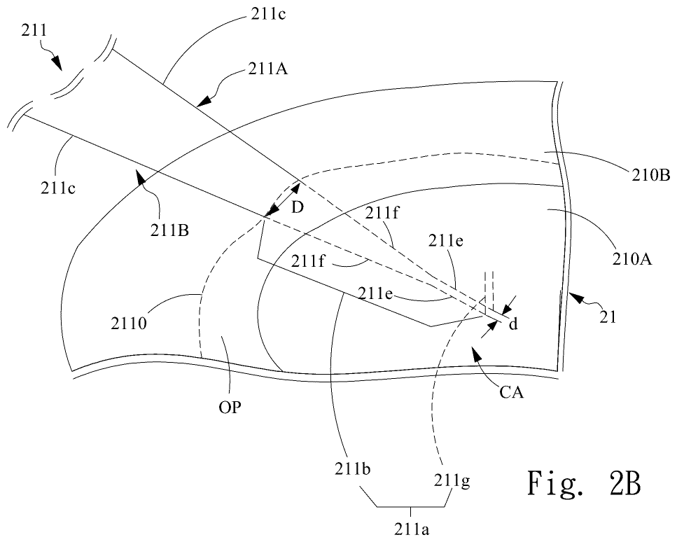

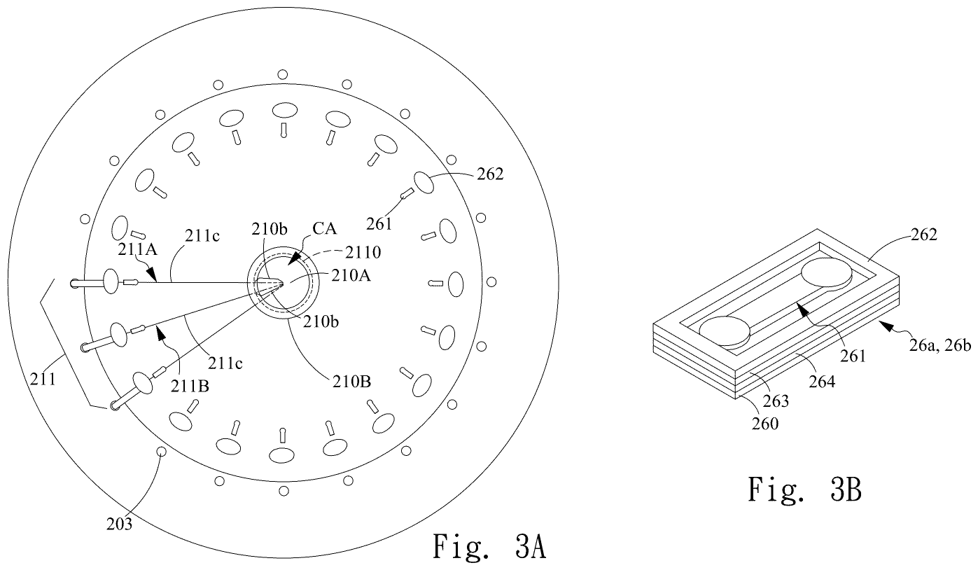

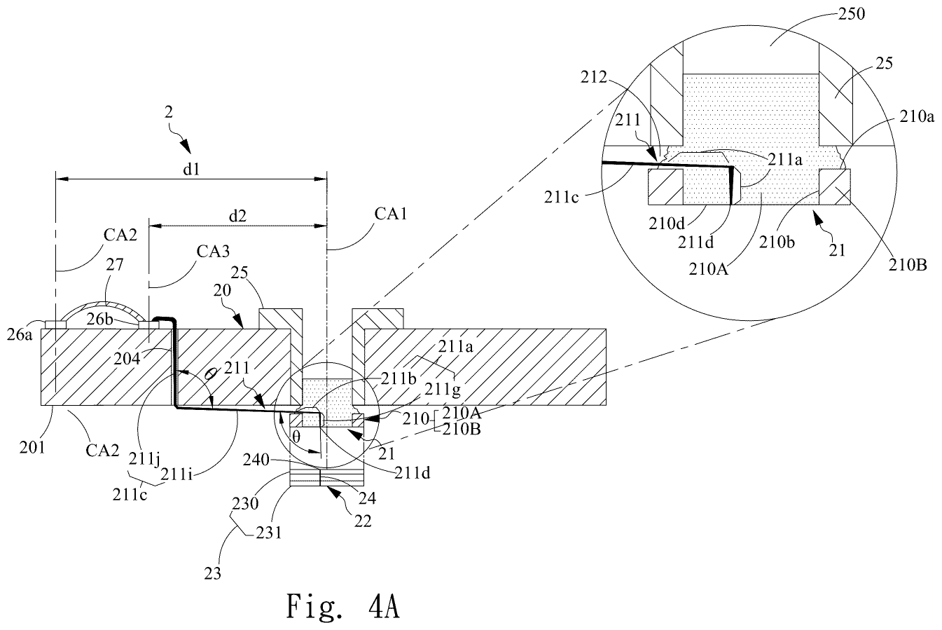

Referring to FIG. 2A, which is a schematic diagram of a third embodiment of the probe card of the present invention. In this embodiment, three cantilever converting probes 211 are used as an example; however, it is not limited to the three cantilever converting probes 21 in the present invention. The cantilever converting probe 211 comprises a first converting probe 211A and a second converting probe 211B adjacent to the first converting probe 211A without contacting with each other. The fixed segments 211a of the first converting probe 211A and the second converting probe 211B respectively have an insertion segment 211b that enters from the lateral side 2110 of the fixing portion 210A. It is noted that the lateral side 2110 described in this embodiment is not limited to insertion from the left side shown in FIG. 1D. As shown in FIG. 3A, the lateral side can be located at any position along the 360-degree edge of the fixing portion 210A. The insertion segment 211b of the plurality of the cantilever converting probes 211 further comprises a head section 211e located away from the lateral side 2110 of the fixing portion 210A, and a tail section 211f adjacent to the lateral side 2110 of the fixing portion. In the head section 211e of the insertion segment 211b of the first converting probe 211A and the second converting probe 211B, the corresponding positions of the two insertion segments 211b have a head shortest distance d. The tail sections 211f of the insertion segments 211b of the first converting probe 211A and the second converting probe 211B have a tail shortest distance D, where the tail shortest distance D is greater than the head shortest distance d. The variation in the probe distance between the shortest distances D and d has no specific limitation. In this embodiment, the shortest distance between D and d are gradually decreased, that is, the shortest distance D at the corresponding positions of the insertion segments 211b of the first converting probe 211A and the second converting probe 211B narrows from the lateral side 2110 of the fixing portion toward the head shortest distance d. By designing the variation of distance, the coupling capacitance interference between the probes can be reduced, thereby improving the accuracy of electrical testing.

Please refer to FIG. 2B which is a schematic diagram of the third embodiment of the probe card according to the present invention. In this embodiment, two cantilever converting probes 211 are used as an example. However, it is not limited to two cantilever converting probes 211 in the probe card of the present invention. In this embodiment, the variation in the probe spacing between the shortest distances D and d is gradually narrowing from the tail shortest distance D toward the head shortest distance d and the probes extend parallelly to the contact section 211g after reaching the shortest distance d at the middle section, which represents another embodiment for reducing coupling capacitance. Specifically, in this embodiment, the plurality of cantilever converting probes 211 comprises a first converting probes 211A and a second converting probes 211B. The first converting probe 211A and the second converting probe 211B are adjacent without contacting with each other. The first converting probe 211A and the second converting probe 211B comprise a fixed segment 211a and an exposed segment 211c, respectively. The fixed segments 211a comprise insertion segments 211b and contact segments 211g, respectively. The insertion segments 211b further comprise head sections 211e, which are farther from the fixing portion 210A and parallel to each other, and tail sections 211f, which are adjacent to lateral side 2110 of the fixing portion and not parallel to each other, wherein the corresponding positions of the head sections 211e of the insertion segments 211b of the first converting probe 211A and the second converting probe 211B defines the shortest head distance d, while the tail sections 211f of the insertion segments 211b of the first converting probe 211A and the second converting probe 211B defines the shortest tail distance D, wherein the shortest tail distance D is greater than the shortest head distance d.

Additionally, in order to prevent the arm of the cantilever converting probe 211 from being bent causing contact segment 211g of the cantilever converting probe to generate lateral displacement such that the contact segment 211g fails to contact with the probe tail 240 of the vertical probe 24 during the measurement, in the present embodiment, the cantilever-type space transformer 21 is arranged on the circuit board 20, the base frame 210B of the mounting base 210 comprises an upper surface 210a facing the circuit board 20 and a first through hole 210b, and the fixing portion 210A is arranged within the first through hole 210b and extends to the upper surface 210a of the base frame 210B thereby filling a gap 212 between the base frame 210B and the circuit board 20 such that the fixed segment 211a is encapsulated by the fixing portion 210A, thereby keeping the contact segment 211g being stationary. The gap 212 further allows the exposed segment 211c of the cantilever converting probe 211 to pass therethrough and enter the fixing portion 210A.

Please refer to FIGS. 3A and 3B. FIG. 3A is a bottom view of the first embodiment of the probe card of the present invention. FIG. 3B is a schematic diagram of one embodiment of the leakage current protection pad of the probe card. To ensure that the probe card can meet the leakage current testing standards, an electrical pad ring is provided on the lower surface 201 of the circuit board 20 for allowing the cantilever-type space transformer soldered thereon so as to ensure that the leakage current can be guided to ground by the guard pattern thereby preventing leakage current from flowing to other electrical contact ring and ensuring the leakage current remains within specification. In this embodiment, the upper surface 200 of the circuit board 20 is provided with the plurality of leakage current protection pad 26a, while the lower surface 201 of the circuit board 20 is provided with multiple leakage current protection contacts 26b. Each leakage current protection pad 26a and 26b is arranged on the circuit board 20 via a base plate 260 to form a leakage current protection structure. In this embodiment, each leakage current protection pad 26a and 26b further comprises a signal circuit pattern 261, which is surrounded by a guard circuit pattern 262. Additionally, a conductive layer 263 and an insulating layer 264 formed on the conductive layer 263 are formed between the base plate 260 and the signal circuit pattern 261. The guard circuit pattern 262 is electrically connected to the conductive layer 263. The conductive layer 263, located beneath the insulating layer 264, provides shielding for the signal circuit pattern 261 along vertical direction. The base plate 260 is further arranged on the surface of the circuit board 20. It should be noted that the configuration of the conductive layer 263 and the insulating layer 264 can be adjusted based on usage requirements without specific limitations. The base plate 260 is mounted on the circuit board 20 using an adhesive material. If the leakage current protection pads fail to meet the leakage current testing standards, the base plate 260 can be removed and replaced with a new base plate 260 containing leakage current protection pads 26a and 26b so as to provide a remedial mechanism to address issues where the pads do not comply with the leakage current testing specifications. It should be noted that the leakage current protection pads 26a and 26b can be a combination of a signal circuit pattern 261 and a guard circuit pattern 262 arranged on a base plate, or, alternatively, a plurality of the signal circuit patterns 261 and guard circuit patterns 262 arranged at intervals and placed on a base plate. There are no specific limitations, and the configuration can be determined based on the actual testing requirements.

Please refer to FIGS. 1D, 3A, and 3B. In this embodiment, the circuit board 20 has a central axis CA1 along its thickness direction. The first leakage current protection pad 26a has a first central axis CA2 along its thickness direction, and the second leakage current protection pad 26b has a second central axis CA3 along its thickness direction. The radial distance d1 between the first central axis CA2 and the circuit board's central axis CA1 is greater than the distance d2 between the second central axis CA3 and the circuit board's central axis CA1. The coaxial cable 27 comprises a central wire in the axial direction, an insulating layer surrounding the central wire, and an outer conductor layer. Both ends of the central wire of the coaxial cable 27 are electrically connected to the signal circuit pattern 261 of the leakage current protection pads 26a and 26b, respectively, while both ends of the outer conductor layer of the coaxial cable 27 are electrically connected to the guard circuit pattern 262 of the leakage current protection pads 26a and 26b, respectively.

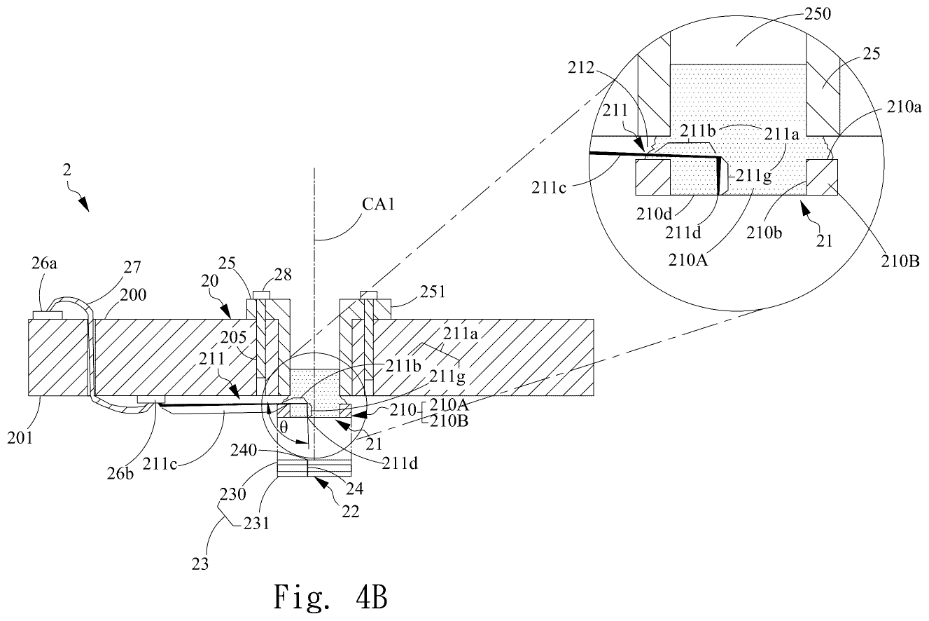

It is noted that the arrangement of the leakage current protection pads 26a and 26b is not limited to the first embodiment. Please refer to FIG. 4A, which is a schematic diagram of the fifth embodiment of the probe card of the present invention. The fifth embodiment is essentially similar to the first embodiment, wherein the different part is that the leakage current protection pads 26a and 26b are arranged on the upper surface 200 of the circuit board 20. The circuit board 20 further comprises a plurality of second through holes 204 for the cantilever converting probe 211 to pass therethrough. In this embodiment, the exposed segment 211c of the cantilever converting probe 211 further comprises a first probe segment 211i and a second probe segment 211j, wherein the first probe segment 211i is connected to the fixed segment 211a, and the second probe segment 211j is connected to the first probe segment 211i with an included angle θ. The second probe segment 211j further passes through the second through hole 204 and is electrically connected to the leakage current protection pad 26b arranged on the upper surface 200. The leakage current protection pad 26b is then electrically connected to the leakage current protection pad 26a through the coaxial cable 27. The plurality of leakage current protection pads 26a and 26b include a plurality of first leakage current protection pad 26a on the upper surface 200 of the circuit board 20 and a plurality of the second leakage current protection pad 26b on the upper surface 201 of the circuit board 20. Both ends of each coaxial cable 27 is electrically connected to the first leakage current protection pad 26a and the second leakage current protection pad 26b, respectively. The center of the circuit board 20 has a central axis CA1 along its thickness direction, the first leakage current protection pad 26a has a first central axis CA2 along its thickness direction, and the second leakage current protection pad 26b has a second central axis CA3 along its thickness direction. The radial distance d1 between the first central axis CA2 and the central axis CA1 of the circuit board is greater than the distance d2 between the second central axis CA3 and the central axis CA1 of the circuit board.

Please refer to FIG. 4B which is a schematic diagram of the sixth embodiment of the probe card of the present invention. The sixth embodiment is essentially similar to the first embodiment wherein the different part is that, in this embodiment, the circuit board 20 is further provided with locking holes 205, which may be through-holes or blind holes. The locking element 28 passes through the abutting ring 251 of the reinforcing member 25, the abutting ring 251 abuts against on the upper surface 200 of the circuit board 20, and the locking element 28 is then secured within the locking hole 205. Moreover, the method of securing the locking element 28 is not limited to this configuration. In another embodiment, the locking element 28 passes through the circuit board 20, abuts against the lower surface 201 of the circuit board 20, and is then secured to the reinforcing member 25. It should be noted that the reinforcing member 25 can be made of a metallic material, with a warpage smaller than that of the circuit board 20. When the cantilever-type space transformer 21 is arranged on the reinforcing member 25, e.g., in this embodiment, the fixing portion 210A of the cantilever-type space transformer 21 connected to the cantilever-type space transformer 21, the flatness is improved compared to the situation that the cantilever-type space transformer 21 is mounted directly on the circuit board 20. Through this structure, when the vertical probe head 22 is replaced, the unstable electrical connection between the vertical probe head 22 and the cantilever-type space transformer due to the warpage of the circuit board 20 could be less affected.

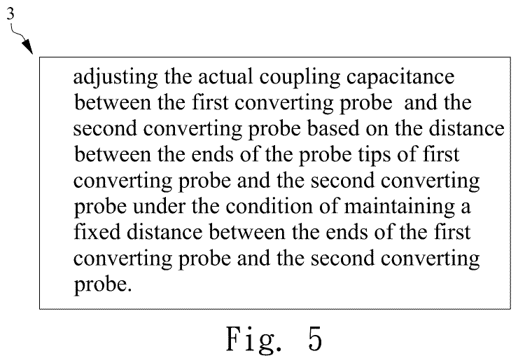

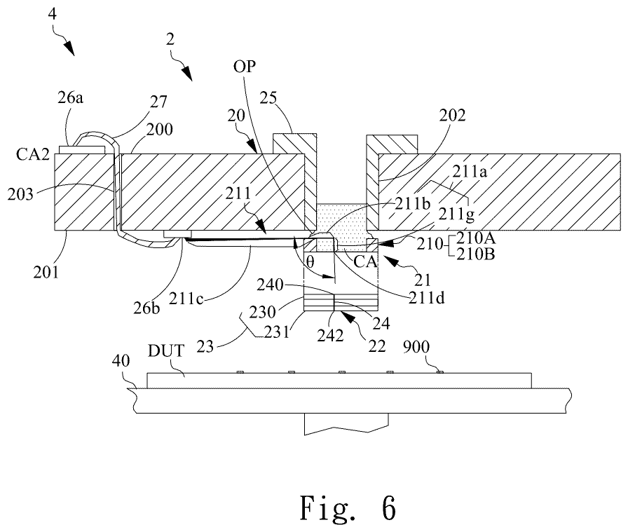

Please refer to FIG. 5 which is a flowchart of one embodiment of the probe card design method of the present invention. In this embodiment, the design method 3 refers to the design and adjustment of the coupling capacitance in the cantilever-type space transformer.

In this embodiment, the described probe card 2 comprises a circuit board 20, a cantilever-type space transformer 21, and a vertical probe head 22. The cantilever-type space transformer 21 is electrically connected to the circuit board 20, while the vertical probe head 22 is electrically connected to the cantilever-type space transformer 21. The cantilever-type space transformer 21 comprises a mounting base 210 and a plurality of cantilever converting probes 211. The structure of the probe card is as previously described and will not be described further hereinafter. The plurality of cantilever converting probes 211 comprise two adjacent a first converting probe 211A and a second converting probe 211B.

The design method 3 comprises a step of adjusting the actual coupling capacitance between the first converting probe 211A and the second converting probe 211B based on the distance between the ends of the probe tips of first converting probe 211A and the second converting probe 211B under the condition of maintaining a fixed distance between the ends of the first converting probe 211A and the second converting probe 211B. The adjustment ensures that the coupling capacitance meets the required capacitance threshold. It is noted that the ends of the first converting probe 211A and the second converting probe 211B corresponds to the positions of probe tail of the vertical probes 24 and the ends of the first converting probe 211A and the second converting probe 211B can be regarded as the probe tip, such as shown in FIG. 2A, wherein the probe tip refers to the distance between the tips 211k of the contact segments 211g. This distance typically corresponds to the pitch of the pads on the DUT; therefore, its size is not limited and can be adjusted according to actual testing requirements. The coupling capacitance threshold is determined based on detection needs and testing conditions, which are usually the testing requirements and conditions specified and provided to the probe card manufacturer by the client.

The adjustment, in one embodiment, is performed by adjusting the relative distance of the fixed segments 211a of the first converting probe 211A and the second converting probe 211B thereby adjusting the actual coupling capacitance between the first converting probe 211A and the second converting probe 211B. For example, in one embodiment of the adjustment, as shown in FIG. 2A, the shortest distance between the corresponding positions of the insertion segments 211b of the first converting probe 211A and the second converting probe 211B are adjusted to gradually narrow from the position entering the lateral side 2110 of the fixing portion 210A thereby resulting in the shortest distance d between the head sections 211e of the two insertion segments 211b and the shortest distance D at the tail sections 211f, where the tail section distance D is greater than the head section distance d, but is not limited thereto instead. For instance, the coupling capacitance can also be adjusted by using the measure shown in FIG. 2B.

After determining the relative positions between the converting probes to meet the coupling capacitance threshold, the fixing portion 210A is then further formed to secure the fixed sections 211a of the first converting probe 211A and the second converting probe 211B.

As shown in FIG. 6 which is a schematic diagram of one embodiment of the testing system of the present invention. In this embodiment, the testing system 4 comprises a carrying platform 40 and a probe card 2. The carrying platform 40 is used to support the DUT, which is the wafer in this case. The DUT has electrical pads 900. The probe card 2 is electrically connected to the DUT through the vertical probes 24 contacting with the electrical pads 900 of the DUT for performing electrical testing. The structure of the probe card 2 is as described earlier and will not be described hereinafter.

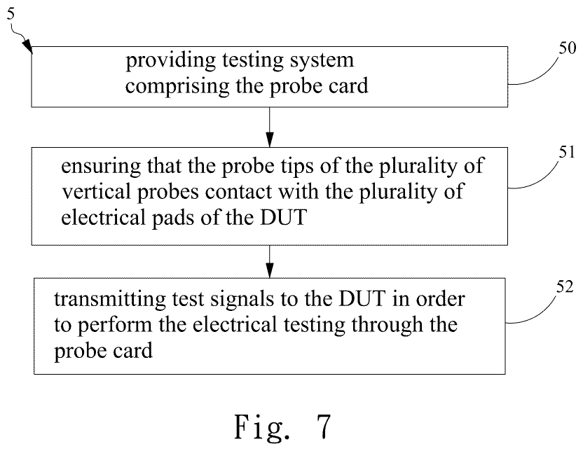

Please refer to FIG. 7, which is a flowchart of one embodiment of the testing method of the present invention. The testing system shown in FIG. 6 is utilized to perform electrical test to the DUT. The method 5 comprises a step 50 for providing the testing system 4 shown in FIG. 6, which comprises the probe card 2 whose structure has been described earlier and will not be described hereinafter, a step 51 for ensuring that the probe tips 242 of the plurality of vertical probes 24 contact with the plurality of electrical pads 900 of the DUT, and finally, a step 52 for transmitting test signals to the DUT in order to perform the electrical testing through the probe card 2.

What is claimed is:

1. A probe card, suitable for conducting a wafer acceptance test on a wafer, the probe card comprising:
a circuit board;
a cantilever-type space transformer, electrically connected to the circuit board; and
a vertical probe head, electrically connected to the cantilever-type space transformer, the vertical probe head comprising:
a probe base, comprising an upper guide plate unit and a lower guide plate unit, wherein the upper guide plate unit comprises at least one upper guide plate and an upper guide hole penetrating through the at least one upper guide plate, the lower guide plate unit comprises at least one lower guide plate and a lower guide hole penetrating through the at least one lower guide plate, and the upper guide plate unit and the lower guide plate unit respectively have an upper surface and a bottom surface, wherein an accommodating space is formed between the lower surface of the upper guide plate unit and the upper surface of the lower guide plate unit; and
a vertical probe, comprising a probe tail, a probe body, and a probe tip, wherein the probe tail passes through the at least one upper guide hole, the probe body is positioned within the accommodating space, and the probe tip passes through the at least one lower guide hole;
wherein the cantilever-type space transformer comprises a mounting base and a cantilever converting probe, the cantilever converting probe comprises a fixed segment and an exposed segment, the fixed segment is secured to the mounting base, the exposed segment is outside the mounting base, and the fixed segment enters from a lateral side of the mounting base and forms a contact on the bottom surface of the mounting base.

2. The probe card according to claim 1, wherein the cantilever converting probe comprises a first converting probe and a second converting probe adjacent to the first converting probe without contacting each other, the fixed segments of the first and second converting probes comprise an insertion segment that enters from the lateral side of the fixing portion, the insertion segment of the cantilever converting probes further comprises a head section located away from the lateral side of the fixing portion and a tail section adjacent to the lateral side of the fixing portion, wherein in the head sections of the insertion segments of the first and second converting probes, the corresponding positions of the two insertion segments have a shortest head distance while in the tail sections of the insertion segments of the first and second converting probes, there is a shortest tail distance, wherein the shortest tail distance is greater than the shortest head distance.

3. The probe card according to claim 2, wherein a shortest distance at the corresponding positions of the insertion segments of the first converting probe and the second converting probe gradually decreases from the position where the insertion segments enter the lateral side of the fixing portion.

4. The probe card according to claim 1, wherein the cantilever-type space transformer is disposed on the circuit board, the mounting base comprises a base frame and a fixing portion, wherein the base frame comprises an upper surface facing the circuit board and a first through-hole, while the fixing portion is positioned within the first through-hole and extends to the upper surface of the base.

5. The probe card according to claim 1, wherein the circuit board further comprises a plurality of leakage current protection pads, each of the plurality of leakage current protection pads is disposed on a base plate mounted on the circuit board via an adhesive material, and the leakage current protection pad further comprises a signal circuit pattern surrounded by a guard circuit pattern.

6. The probe card according to claim 5, wherein the probe card further comprises a plurality of coaxial cables respectively electrically connected to the leakage current protection pads.

7. The probe card according to claim 6, wherein the circuit board further comprises a plurality of through holes for allowing the coaxial cables or the cantilever converting probes to pass therethrough.

8. The probe card according to claim 5, wherein the leakage current protection pads include a plurality of first leakage current protection pads on the upper surface of the circuit board and a plurality of second leakage current protection pads on the circuit board, two ends of each coaxial cable are electrically connected to the first and second leakage current protection pads, respectively, the circuit board has a central axis along its thickness direction, the first leakage current protection pad has a first central axis along its thickness direction, and the second leakage current protection pad has a second central axis along its thickness direction, wherein a radial distance between the first central axis and the circuit board central axis is greater than the radial distance between the second central axis and the circuit board central axis.

9. The probe card according to claim 1, wherein the probe card further comprises a reinforcing member, the reinforcing member detachably mounted on the circuit board, the mounting base is connected to the reinforcing member.

10. The probe card according to claim 9, wherein the reinforcing member is secured on the circuit board by a fastening element.

11. The probe card according to claim 9, wherein the mounting base comprises a base frame, which has an upper surface facing the circuit board and a first through-hole, the reinforcing member has a second through-hole corresponding to the first through-hole, the fixing portion is positioned within the first and second through-holes and extends to the upper surface of the base frame, wherein a gap is formed between the base frame and the circuit board thereby allowing the exposed segments of the cantilever converting probes to pass therethrough.

12. The probe card according to claim 1, wherein the material of the cantilever converting probe is beryllium, copper, rhenium, tungsten, gold, silver, or an alloy selected from at least two of thereof.

13. The probe card according to claim 1, wherein the pad of each cantilever converting probe is either an end portion on a probe body of the fixed section, or a pad coupled to the end portion of the probe body of the fixed section.

14. The probe card according to claim 1, wherein the fixed section is formed as a conical shape.

15. The probe card according to claim 1, wherein a hardness of the cantilever converting probe is greater than 245 MPa, and the resistance of the cantilever converting probe is less than 200 mΩ.

16. A method for designing probe card, wherein the probe card comprises a circuit board, a cantilever-type space transformer, and a vertical probe head, the cantilever-type space transformer is electrically connected to the circuit board, and the vertical probe head is electrically connected to the cantilever-type space transformer, the cantilever-type space transformer comprises a mounting base and a plurality of cantilever converting probes comprising a first converting probe and a second converting probe that are adjacent to each other, and the method comprises a step of:
adjusting an actual coupling capacitance between the first and second converting probes to meet a coupling capacitance threshold based on a distance between ends of the first converting probe and the second converting probe, under a condition that distance between the ends of the first and second converting probes is fixed.

17. The method according to claim 16, wherein the mounting base of the cantilever-type space transformer comprises a fixing portion, and each cantilever converting probe sequentially comprises a fixed segment and an exposed segment, wherein the fixed segment is secured to the fixing portion of the mounting base, and the exposed section is outside the fixing portion for electrically connecting to the circuit board, wherein the step of adjusting the actual coupling capacitance between the first and second converting probes further comprises a step of:
adjusting a relative distance between the fixed segments of the first and second converting probes so as to modify the actual coupling capacitance between the first and second converting probes.

18. The method according to claim 17, wherein the fixed segment enters from a lateral side of the fixing portion, and a contact is formed on a bottom surface of the fixing portion of the mounting base, each contact is used for electrically contacting with probe tails of the vertical probes, each fixed segments of the first and second converting probes has an insertion segment that enters from the lateral side of the fixing portion, wherein the step of adjusting the relative distance of the fixed segments of the first and second converting probes further comprises a step of:
adjusting a shortest distance with respect to the corresponding positions of the insertion segments of the first and second converting probes to be gradually decreased from the position that the insertion segments enter the lateral side of the fixing portion.

19. A test method comprising:
proving the probe card according to claim 1;
making a plurality of probe tips of the vertical probe of the probe card correspondingly contact with a plurality of conductive pads of a device under test; and
transmitting a test signal to the device under test through the probe card.

20. A testing system, comprising:
a carrying chuck suitable for carrying a device under test; and
a probe card according to claim 1, wherein the probe card is electrically connected to the device under test through a contact between the vertical probe of the probe card and the device under test.
